(19) United States
(12) Patent Application Publication
(10) Pub. No.: US 2010/0313660 A1
(43) Pub. Date: Dec. 16, 2010

(54) MEMS DEVICE AND METHOD OF FABRICATING THE MEMS DEVICE

(75) Inventors: Haruhiko Nishikage, Kyoto (JP); Hironobu Kawauchi, Kyoto (JP); Toma Fujita, Kyoto (JP)

Correspondence Address: FISH & RICHARDSON P.C. (NY), P.O. BOX 1022, MINNEAPOLIS, MN, 55440-1022, US

(73) Assignee: Rohm Co., Ltd., Kyoto (JP)

(21) Appl. No.: 12/813,812

(22) Filed: Jun. 11, 2010

(30) Foreign Application Priority Data
Jun. 15, 2009 (JP) 2009-142226
May 25, 2010 (JP) 2010-119282

(51) Int. Cl. G01P 15/125; H01L 21/302

(52) U.S. Cl. 73/514.32; 438/50; 257/E21.214

(57) ABSTRACT

A MEMS device capable of detecting external force with high sensitivity is disclosed. The MEMS device includes: first and second support portions arranged on a substrate; a first movable portion that has a first movable electrode, is fixed to the first support portion at a position apart from the first movable electrode, and is displaced by the external force; and a second movable portion that has a second movable electrode arranged opposite to the first movable electrode, is fixed to the second support portion at a position apart from the second movable electrode, and is displaced by the external force, wherein the first movable portion is fixed to the first support portion between a gravitational center position of the first movable portion and an opposite position where the first movable electrode and the second movable electrode are opposed to each other, and the second movable portion is fixed to the second support portion at a position opposed to the opposite position while sandwiching a gravitational center position of the second movable portion therebetween.

### CROSS REFERENCE TO RELATED APPLICATIONS AND INCORPORATION BY REFERENCE

This application is based upon and claims the benefits of priority from prior Japanese Patent Applications Nos. P2009-142226 and P2010-119282 filed on Jun. 15, 2009 and May 25, 2010, respectively, the entire contents of which are incorporated herein by reference.

### TECHNICAL FIELD

The present invention relates to a MEMS device including a movable portion that is displaced in response to force applied thereto from an outside, and to a method of fabricating the MEMS device.

### BACKGROUND ART

A micro electro mechanical system (MEMS) device including a movable portion that is displaced in response to force applied thereto from an outside (hereinafter, referred to as “external force”) is used as a sensor such as an acceleration sensor and a gyro sensor, which senses a physical quantity. For example, an electrostatic capacitance type acceleration sensor is proposed, which senses a change of electrostatic capacitance between the movable portion that oscillates by the external force and a fixed portion, thereby detects an acceleration (for example, refer to Patent Literature 1).

### Citation List

Patent Literature 1: Specification of U.S. Pat. No. 6,792,804 (B2)

### SUMMARY OF THE INVENTION

### Technical Problem

However, in such a method of sensing the physical quantity based on the change of the electrostatic capacitance, which occurs by a change of a distance between the movable portion and the fixed portion, there has occurred a problem that it is difficult to detect the physical quantity such as the acceleration in the case where a displacement of the movable portion by the external force is small, and so on. Therefore, it is desired that sensitivity of the MEMS device for the external force applied thereto be enhanced.

It is an object of the present invention to provide a MEMS device capable of detecting the external force with high sensitivity, and to provide a method of fabricating the MEMS device.

### Solution to Problem

In accordance with an aspect of the present invention, a MEMS device is provided, which includes: a substrate; a first support portion and a second support portion, the first and second support portions being arranged on the substrate; a first movable portion that has a first movable electrode, is fixed to the first support portion at a position apart from the first movable electrode, and is displaced by external force; and a second movable portion that has a second movable electrode arranged opposite to the first movable electrode, is fixed to the second support portion at a position apart from the second movable electrode, and is displaced by the external force, wherein the first movable portion is fixed to the first support portion between a gravitational center position of the first movable portion and an opposite position where the first movable electrode and the second movable electrode are opposed to each other, and the second movable portion is fixed to the second support portion at a position opposed to the opposite position while sandwiching a gravitational center position of the second movable portion therebetween.

In accordance with another aspect of the present invention, a method of fabricating a MEMS device including a first movable portion and a second movable portion opposed to the first movable portion is provided, which includes the steps of: forming an upper insulating film on an upper surface of a substrate made of single crystal; patterning the upper insulating film, and forming trenches; filling an insulating film into the trenches, and forming insulating isolation regions; patterning the upper insulating film, and forming a metal electrode layer on an entire device surface; patterning the metal electrode layer, and forming a first movable portion-purpose wring electrode connected to the first movable portion and a second movable portion-purpose wiring electrode connected to the second movable portion; etching the substrate to a predetermined depth by selective etching using the upper insulating film as a mask; depositing an insulating film on the entire device surface, and forming sidewall insulating films on sidewall portions of etched grooves; removing by etching the insulating films deposited on the device surface and bottom surfaces of the etched grooves, and exposing respective surfaces of the first movable portion-purpose wiring electrode and the second movable portion-purpose wiring electrode; and by isotropic etching for the substrate, forming spaces, and forming the first movable portion and the second movable portion, the first and second movable portion being obtained by patterning the substrate.

### Advantageous Effects of Invention

In accordance with the present invention, it is possible to provide the MEMS device capable of detecting the external force with high sensitivity, and to provide the method of fabricating the MEMS device.

### BRIEF DESCRIPTION OF DRAWINGS

FIG. 1A is a schematic plan view showing a configuration of a MEMS device according to a first embodiment.

FIG. 1B is a side view of the MEMS device shown in FIG. 1A.

FIG. 2A is a schematic view for explaining operations of the MEMS device according to the first embodiment, and is a side view in a case where a gravitational acceleration G is not applied to the MEMS device.

FIG. 2B is a side view in a case where the gravitational acceleration G is applied to the MEMS device in a −z-direction.

FIG. 3 is a schematic view showing an example where a warp is generated in a movable portion of the MEMS device according to the first embodiment.

FIG. 4 is a schematic view showing a state where the gravitational acceleration G is applied to the MEMS device shown in FIG. 3 in the −z-direction.

FIG. 5 is a schematic view showing a state where the gravitational acceleration G is applied to the MEMS device shown in FIG. 3 in a +z-direction.

FIG. 6A is a schematic view showing another example where the warp is generated in the movable portion of the MEMS device according to the first embodiment, and is a side view showing a state where the gravitational acceleration G is not applied to the MEMS device.

FIG. 6B is a side view showing a state where the gravitational acceleration G is applied to the MEMS device shown in FIG. 6A in the +z-direction.

FIG. 7 is a schematic view showing an example of a movable portion of the MEMS device according to the first embodiment, which is capable of detecting a direction where the gravitational acceleration G is applied.

FIG. 8 is a schematic plan view showing a configuration of a modification example of the MEMS device according to the first embodiment.

FIG. 9 is a schematic plan view for explaining a method of fabricating the MEMS device according to the first embodiment.

FIG. 10 is a process cross-sectional view for explaining the method of fabricating the MEMS device according to the first embodiment (No. 1).

FIG. 11 is a process cross-sectional view for explaining the method of fabricating the MEMS device according to the first embodiment (No. 2).

FIG. 12 is a process cross-sectional view for explaining the method of fabricating the MEMS device according to the first embodiment (No. 3).

FIG. 13 is a process cross-sectional view for explaining the method of fabricating the MEMS device according to the first embodiment (No. 4).

FIG. 14 is a process cross-sectional view for explaining the method of fabricating the MEMS device according to the first embodiment (No. 5).

FIG. 15A is a schematic plan view showing a configuration of a MEMS device according to a second embodiment.

FIG. 15B is a schematic cross-sectional structure view of the MEMS device shown in FIG. 15A, taken along a line in FIG. 15A.

FIG. 16 is a schematic cross-sectional structure view of the MEMS device shown in FIG. 15A, taken along a line of FIG. 15A, showing a state where the gravitational acceleration G is applied to the MEMS device in the −z-direction.

FIG. 17 is a schematic plan view showing a configuration of a MEMS device according to a modification example of the second embodiment.

FIG. 18A is a schematic cross-sectional structure view of the MEMS device shown in FIG. 17, taken along a line IV-IV of FIG. 17, and is a side view showing a position of a movable portion in a case where the gravitational acceleration G is not applied to the MEMS device.

FIG. 18B is a side view showing a position of the movable portion in a case where the gravitational acceleration G is applied to the MEMS device in the −z-direction.

FIG. 18C is a side view showing a position of the movable portion in a case where the gravitational acceleration G is applied to the MEMS device in the +z-direction.

FIG. 19 is a schematic plan view of a MEMS device according to a third embodiment.

FIG. 20 is a schematic cross-sectional structure view of the MEMS device shown in FIG. 19A, taken along a line V-V in FIG. 19.

FIG. 21 is a process cross-sectional view for explaining a method of fabricating the MEMS device according to the third embodiment (No. 1).

FIG. 22 is a process cross-sectional view for explaining the method of fabricating the MEMS device according to the third embodiment (No. 2).

FIG. 23 is a process cross-sectional view for explaining the method of fabricating the MEMS device according to the third embodiment (No. 3).

FIG. 24 is a process cross-sectional view for explaining the method of fabricating the MEMS device according to the third embodiment (No. 4).

FIG. 25 is a process cross-sectional view for explaining the method of fabricating the MEMS device according to the third embodiment (No. 5).

FIG. 26 is a process cross-sectional view for explaining the method of fabricating the MEMS device according to the third embodiment (No. 6).

FIG. 27 is a process cross-sectional view for explaining the method of fabricating the MEMS device according to the third embodiment (No. 7).

FIG. 28 is a process cross-sectional view for explaining the method of fabricating the MEMS device according to the third embodiment (No. 8).

FIG. 29 is a process cross-sectional view for explaining the method of fabricating the MEMS device according to the third embodiment (No. 9).

### DESCRIPTION OF EMBODIMENTS

Next, a description is made of embodiments with reference to the drawings. In the following description referring to the drawings, the same or similar reference numerals are assigned to the same or similar portions. However, the drawings are schematic, and it should be noted that a relationship between thicknesses and planar dimensions, a ratio of thicknesses of the respective layers, and the like are different from the actual ones. Hence, specific thicknesses and dimensions should be determined in consideration of the following description. Moreover, it is a matter of course that portions different in dimensional relationship and ratio are also included among the respective drawings.

Moreover, the embodiments to be described below illustrate devices and methods, which are for embodying the technical idea of this invention, and the embodiments of this invention do not specify materials, shapes, structures, arrangements and the like of constituent components to those in the following description. The embodiments of this invention can be modified in various ways within the scope of claims.

### First Embodiment

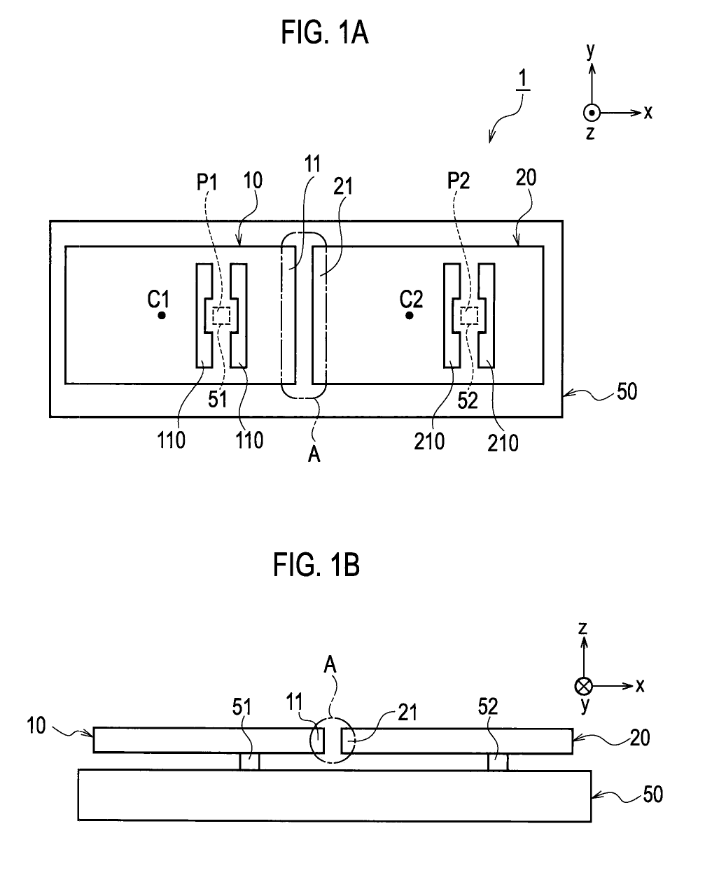

As shown in FIG. 1A and FIG. 1B, a MEMS device 1 according to a first embodiment includes: a substrate 50; a first support portion 51 and a second support portion 52, which are arranged on the substrate 50; a first movable portion 10 that has a first movable electrode 11, is fixed to the first support portion 51 at a position apart from the first movable electrode 11, and is displaced by external force; and a second movable portion 20 that has a second movable electrode 21 arranged opposite to the first movable electrode 11, is fixed to the second support portion 52 at a position apart from the second movable electrode 21, and is displaced by the external force. Between a gravitational center position C1 of the first movable portion 10 and a position A (opposite position A) where the first movable electrode 11 and the second movable electrode 21 are opposed to each other, the first movable portion 10 is fixed to the first support portion 51. At a position opposed to the opposite position A while sandwiching a gravitational center position C2 of the second movable portion 20 therebetween, the second support portion 52 is fixed to the second movable portion 20. Here, the “gravitational center positions” are physical positions of the gravitational centers, which are determined in response to shapes and mass distributions of the first movable portion 10 and the second movable portion 20.

In the MEMS device 1 shown in FIG. 1A, the first movable portion 10 is fixed to the first support portion 51 at a support position P1 in a beam portion sandwiched between slits 110, and the second movable portion 20 is fixed to the second support portion 52 at a support position P2 in a beam portion sandwiched between slits 210. Therefore, connection portions of the first movable portion 10 and the second movable portion 20 to the substrate 50 have flexibility, and the first movable portion 10 and the second movable portion 20 are likely to oscillate by the external force. In such a way, detection sensitivity of the MEMS device 1 is enhanced.

In FIG. 1A, a direction perpendicular to a page surface thereof is defined as a z-direction, and a right-and-left direction on the page surface, that is, a direction of a straight line that connects the gravitational center position C1 of the first movable portion 10 and the gravitational center position C2 of the second movable portion 20 to each other is defined as an x-direction. Moreover, a direction perpendicular to the x-direction on the page surface, that is, an up-and-down direction thereon is defined as a y-direction. Note that a direction perpendicularly upward from the page surface is defined as a positive z-direction (+z-direction), and a direction toward the gravitational center position C2 from the gravitational center position C1 is defined as a positive x-direction (+x-direction).

Hence, when viewed along the x-direction where the gravitational center position C1 and the gravitational center position C2 are connected to each other, the gravitational center position C1, the support position P1 and the opposite position A where the first movable electrode 11 and the second movable electrode 21 are opposed to each other are sequentially arranged, and the opposite position A, the gravitational center position C2 and the support position P2 are sequentially arranged.

The first movable portion 10 and the second movable portion 20 are oscillators which oscillate about positions thereof fixed individually to the first support portion 51 and the second support portion 52, such fixed positions being taken as fulcrums. When the external force in the z-direction is applied from the outside to the MEMS device 1, a distance between the first movable electrode 11 and the second movable electrode 21 is changed. Therefore, when the external force is applied to the MEMS device 1 in a state where a voltage is applied to the first movable electrode 11 and the second movable electrode 21, the change of the distance between the first movable electrode 11 and the second movable electrode 21 is sensed as a change of electrostatic capacitance between the first movable electrode 11 and the second movable electrode 21.

The MEMS device 1 according to the first embodiment transmits the sensed change of the electrostatic capacitance to a signal processing circuit (not shown) by a detection signal. The signal processing circuit processes the detection signal and detects a gravitational acceleration G applied to the MEMS device 1 according to the first embodiment. Specifically, the MEMS device 1 according to the first embodiment is a part of an electrostatic capacitance type acceleration sensor that detects the gravitational acceleration G based on the change of the electrostatic capacitance. The signal processing circuit may be arranged on the same chip as a chip on which the MEMS device 1 according to the first embodiment is arranged, or may be arranged on a different chip from the chip on which the MEMS device 1 according to the first embodiment is arranged.

Note that the first movable electrode 11 and the second movable electrode 21 may be formed by individually arranging electrodes such as metal films on the first movable portion 10 and the second movable portion 20, which are made of a semiconductor, an insulator or the like. Alternatively, the first movable portion 10 and the second movable portion 20 may be used as the first movable electrode 11 and the second movable electrode 21, respectively. In this case, it is necessary that the first movable portion 10 and the second movable portion 20 be electrically insulated from each other.

A description is made below of operations of the MEMS device 1 according to the first embodiment. When the external force is applied to the MEMS device 1 along the z-direction, one of the first movable portion 10 and the second movable portion 20 is displaced in a direction where the external force is applied, and the other thereof is displaced in a reverse direction to the direction where the external force is applied. The direction where the first movable portion 10 is displaced is determined by a positional relationship between the gravitational center position C1 and the support position P1, and the direction where the second movable portion 20 is displaced by a positional relationship between the gravitational center position C2 and the support position P2. Specifically, at the opposite position A, the first movable electrode 11 of the first movable portion 10 is displaced in the reverse direction to the direction where the external force is applied, and the second movable electrode 21 of the second movable portion 20 is displaced in the direction where the external force is applied.

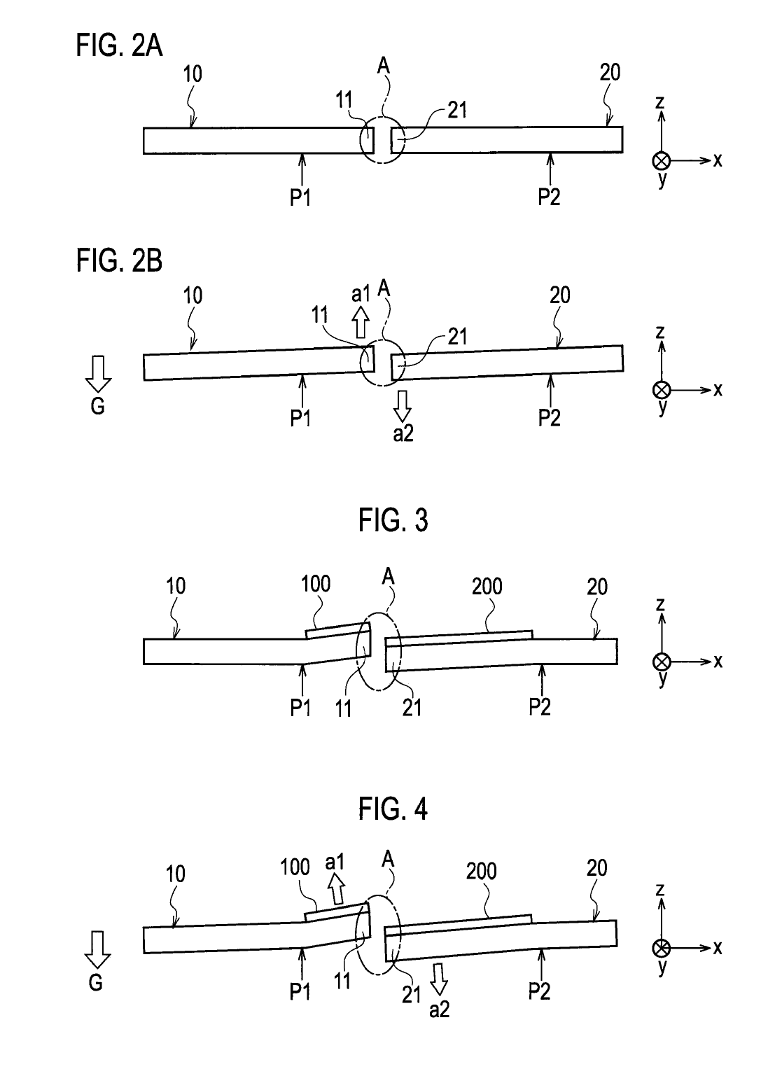

FIG. 2A shows a state of the first movable portion 10 and the second movable portion 20 in a case where the gravitational acceleration G in the z-direction is not applied to the MEMS device 1 according to the first embodiment. Here, for example, when the gravitational acceleration G is applied in the −z-direction to the MEMS device 1 as shown in FIG. 2B, the first movable electrode 11 is displaced in the +z-direction as shown by an arrow a1. Meanwhile, the second movable electrode 21 is displaced in the −z-direction as shown by an arrow a2. By using the change of the electrostatic capacitance between the first movable electrode 11 and the second movable electrode 21, which is caused as a result of this, the gravitational acceleration G applied to the MEMS device 1 according to the first embodiment is detected.

In the related art of sensing a physical quantity such as the gravitational acceleration G by a change of the electrostatic capacitance, which is generated in such a manner that a distance between a movable electrode and a fixed electrode is changed, the sensitivity can be enhanced by increasing a displacement amount of the movable electrode. However, when the displacement amount of the movable electrode is increased, rigidity of an elastic coupling portion that supports the movable electrode is reduced, and there occurs a problem that a resonant frequency of the MEMS device is decreased.

However, in the MEMS device 1 according to the first embodiment, the first movable electrode 11 and the second movable electrode 21 are displaced in the directions reverse to each other. Therefore, a variation of the electrostatic capacitance between the first movable electrode 11 and the second movable electrode 21 is larger than a variation of the electrostatic capacitance between the movable electrode and the fixed electrode, in which the displacement amounts are approximately the same as those of the first movable electrode 11 and the second movable electrode 21. In other words, in order to obtain the same amount of variation of the electrostatic capacitance, a displacement amount of each of the first movable electrode 11 and the second movable electrode 21 in the MEMS device 1 is only a half of the displacement amount of the movable electrode in the MEMS device using the movable electrode and the fixed electrode.

Hence, in accordance with the MEMS device 1 according to the first embodiment, unlike the method of increasing the displacement amount of the movable electrode, the variation of the electrostatic capacitance can be increased without reducing the rigidity of the elastic coupling portion that supports the first movable electrode 11 and the second movable electrode 21. As a result, the MEMS device 1 according to the first embodiment can detect the external force with high sensitivity.

Note that, at the opposite position A, an upper surface of the first movable electrode 11 and an upper surface of the second movable electrode 21 are not allowed to be flush with each other, whereby the direction of the gravitational acceleration G can be sensed.

For example, as shown in FIG. 3, a cap layer 100 different in coefficient of linear expansion from the first movable portion 10 is formed on a part of the upper surface of the first movable portion 10, and a cap layer 200 different in coefficient of linear expansion from the second movable portion 20 is formed on apart of the upper surface of the second movable portion 20. As a result, owing to a thermal stress, a warp is caused between the first movable portion 10 and the second movable portion 20. At this time, materials different in coefficient of thermal expansion from each other are used as the cap layer 100 and the cap layer 200, whereby a warp direction and a warp amount are different between the first movable portion 10 and the second movable portion 20. For example, FIG. 3 shows an example where the warp direction is different between the first movable portion 10 and the second movable portion 20. Specifically, in a state shown in FIG. 3, where the external force is not applied in the z-direction, the upper surface of the first movable electrode 11 and the upper surface of the second movable electrode 21 do not become flush with each other at the opposite position A. Note that the materials of the cap layers 100 and 200 maybe either insulators or conductors.

In the case where the upper surface of the first movable electrode 11 is located at a higher position than the upper surface of the second movable electrode 21 as shown in FIG. 3, when the gravitational acceleration G in the −z-direction is applied to the MEMS device 1 as shown in FIG. 4, the first movable electrode 11 is displaced in the +z-direction as shown by the arrow a1, and the second movable electrode 21 is displaced in the −z-direction as shown by the arrow a2. Therefore, the electrostatic capacitance between the first movable electrode 11 and the second movable electrode 21 is reduced uniformly.

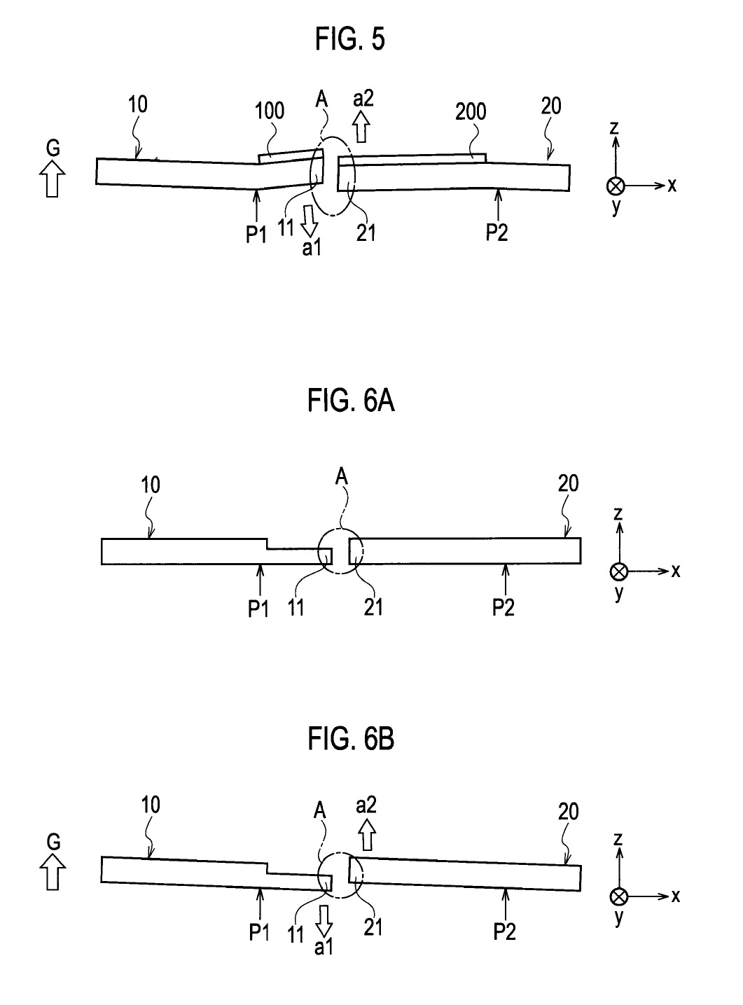

Meanwhile, when the gravitational acceleration Gin the +z-direction is applied to the MEMS device 1 as shown in FIG. 5, the first movable electrode 11 is displaced in the −z-direction as shown by the arrow a1, and the second movable electrode 21 is displaced in the +z-direction as shown by the arrow a2. Therefore, the upper surface of the first movable electrode 11 and the upper surface of the second movable electrode 21 first approach each other, and the electrostatic capacitance between the first movable electrode 11 and the second movable electrode 21 is increased. Hence, the direction of the gravitational acceleration G can be sensed based on an initial variation in the electrostatic capacitance between the first movable electrode 11 and the second movable electrode 21.

FIG. 3 shows the case of arranging the cap layer 100 and the cap layer 200 on the upper surfaces of the first movable portion 10 and the second movable portion 20; however, the cap layers may be arranged on lower surfaces of the first movable portion 10 and the second movable portion 20. Moreover, the cap layer may be arranged on either one of the first movable portion 10 and the second movable portion 20.

FIG. 3 to FIG. 5 show the example of giving a step difference in the z-direction between the first movable electrode 11 and the second movable electrode 21 by the thermal stress. As shown in FIG. 6, at the opposite position A, a film thickness of the first movable portion 10 and a film thickness of the second movable portion 20 are differentiated from each other, whereby the step difference in the z-direction may be given between the first movable electrode 11 and the second movable electrode 21. FIG. 6A shows an example where a part of the first movable portion 10 is thinned, and the film thickness of the second movable portion 20 is made uniform, whereby the upper surface of the first movable portion 10 is made lower than the upper surface of the second movable portion 20. When the gravitational acceleration G in the +z-direction is applied to the MEMS device 1 as shown in FIG. 6B, the upper surface of the first movable electrode 11 and the upper surface of the second movable electrode 21 further depart from each other, and accordingly, the electrostatic capacitance between the first movable electrode 11 and the second movable electrode 21 is reduced uniformly. Therefore, the direction of the gravitational acceleration can be sensed based on a way of the change of the electrostatic capacitance between the first movable electrode 11 and the second movable electrode 21. Note that the cap layer may be arranged on either the first movable portion 10 or the second movable portion 20 after a part thereof is thinned.

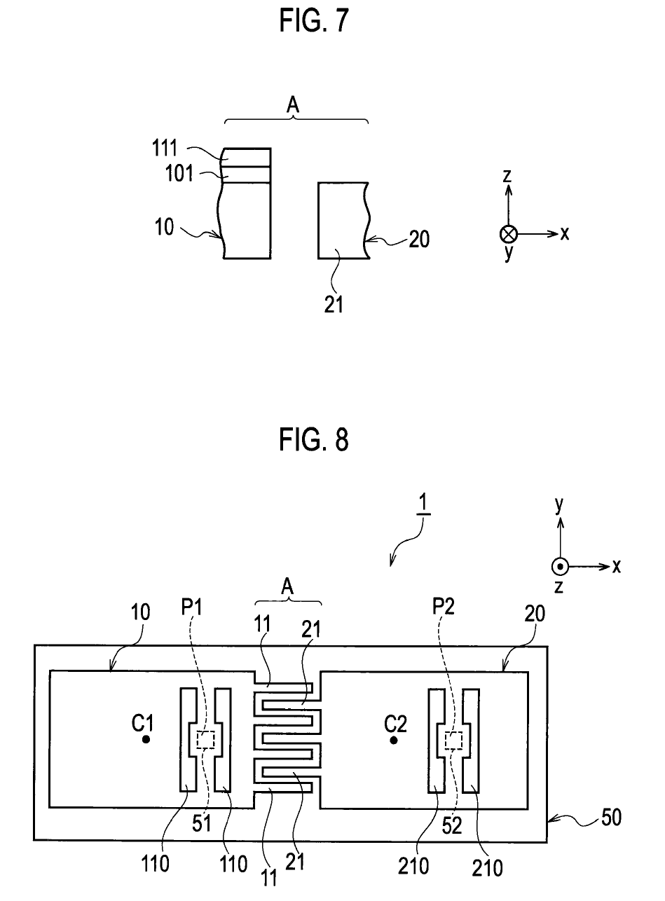

Moreover, as shown in FIG. 7, an insulating film 101 may be arranged on the upper surface of the first movable portion 10, and on the insulating film 101, a conductor film 111 may be arranged as the first movable electrode 11. Also in a structure shown in FIG. 7, the upper surface of the first movable electrode 11 and the upper surface of the second movable electrode 21 are not flush with each other, and the direction of the gravitational acceleration G can be sensed based on the way of the change of the electrostatic capacitance between the conductor film 111 and the second movable electrode 21.

As described above, in the MEMS device 1 according to the first embodiment, the change of the electrostatic capacitance between the first movable electrode 11 and the second movable electrode 21, which are displaced in the directions reverse to each other in the case where the external force is applied to the MEMS device 1, is sensed. Hence, in accordance with the MEMS device 1 according to the first embodiment, the external force applied to the MEMS device 1 can be detected with high sensitivity as compared with the related art of sensing the change of the electrostatic capacitance between the movable portion and the fixed portion.

FIG. 8 shows a MEMS device 1 according to a modification example of the first embodiment. In the MEMS device 1 shown in FIG. 8, shapes of mutually opposed portions of the first movable portion 10 and the second movable portion 20 are individually comb-tooth shapes, and the first movable electrode 11 and the second movable electrode 21 are arranged in an interdigital fashion.

Therefore, opposed areas of the first movable electrode 11 and the second movable electrode 21 are increased, and the electrostatic capacitance between the first movable electrode 11 and the second movable electrode 21 is increased. Hence, the external force can be sensed with high sensitivity.

### (Fabrication Method)

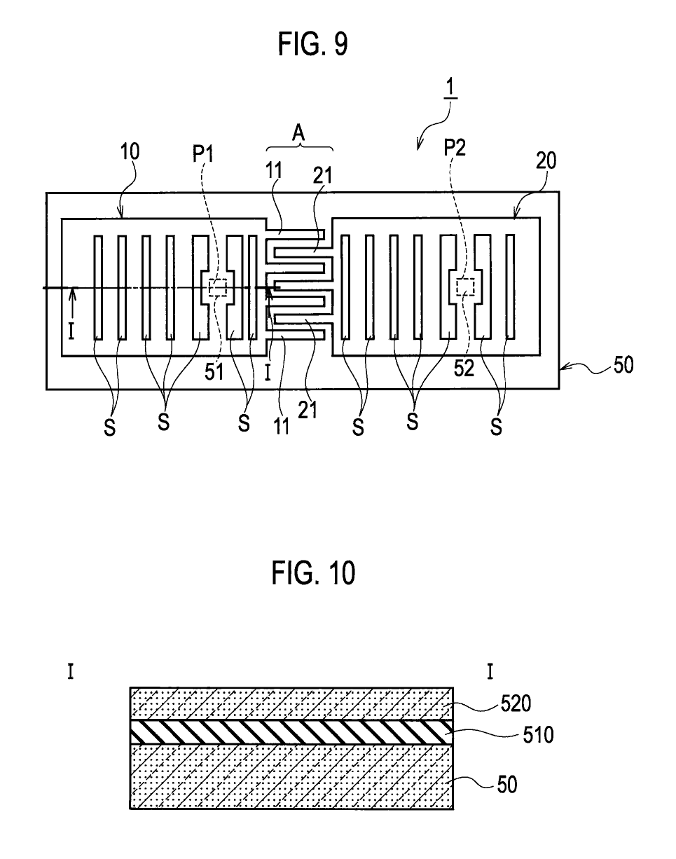

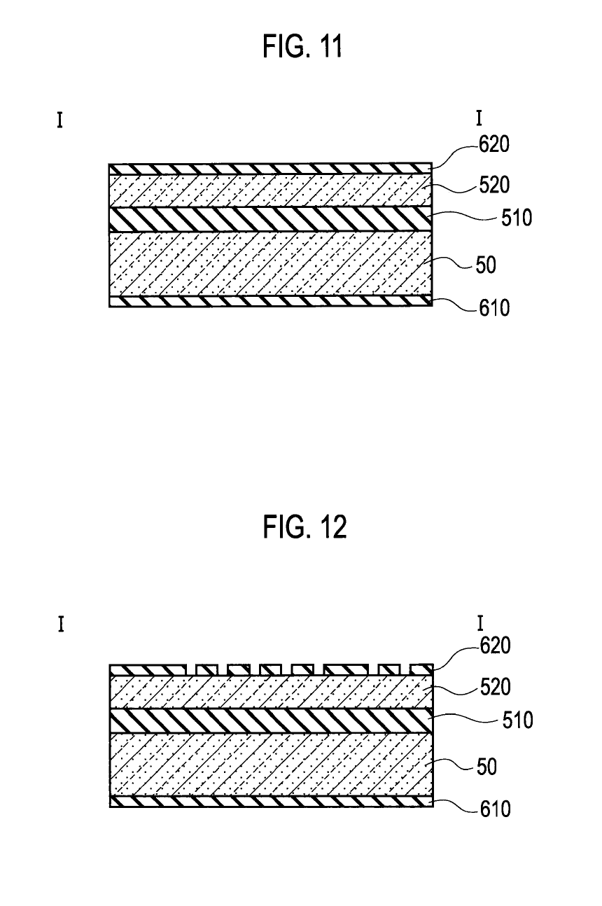

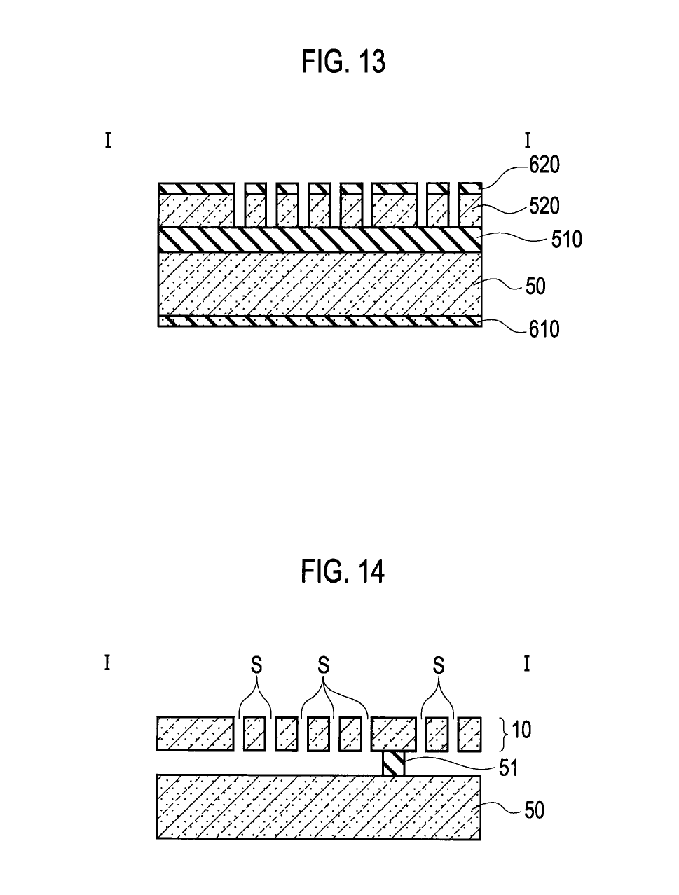

By using a MEMS device 1 shown in FIG. 9 as an example, a description is made of a method of fabricating the MEMS device 1 according to the first embodiment. In the MEMS device 1 shown in FIG. 9, a plurality of slits S which penetrate the first movable portion 10 and the second movable portion 20 from the upper surfaces thereof to the lower surfaces thereof are formed. These slits S are used in an etching step for separating the first movable portion 10 and the second movable portion 20 from the substrate 50. A description is made below of the method of fabricating the MEMS device 1 according to the first embodiment with reference to FIG. 10 to FIG. 14 which correspond to a cross section along a line I-I of FIG. 9. Although not shown, the second movable portion 20 is also formed in a similar way. Note that the method of fabricating the MEMS device 1, which is described below, is merely an example, and it is a matter of course that the MEMS device 1 is realizable by other various fabrication methods including modification examples of the method to be described below.
(a) As shown in FIG. 10, an SOI structure obtained by stacking the substrate 50, an insulator layer 510 and a semiconductor layer 520 on one another is prepared. For example, a silicon (Si) substrate is adoptable for the substrate 50, a silicon oxide (SiO₂) film is adoptable for the insulator layer 510, and a Si film is adoptable for the semiconductor layer 520.
(b) For example, by using a thermal oxidation method, an upper insulating film 620 is formed on an upper surface of the semiconductor layer 520, and a lower insulating film 610 is formed on a lower surface of the substrate 50. The upper insulating film 620 and the lower insulating film 610 are insulator films such as SiO₂ films.
(c) A photoresist film (not shown) is formed on the upper insulating film 620, and this photoresist film is patterned into a desired shape by using a photolithography technology. Then, by selective etching using the patterned photoresist film as a mask, a part of the upper insulating film 620 is removed as shown in FIG. 12.
(d) By the selective etching using the upper insulating film 620 as the etching mask, as shown in FIG. 13, a part of the semiconductor layer 520 is removed by etching until a surface of the insulator layer 510 is exposed. For the etching of the semiconductor layer 520, the Bosch process using a deep reactive ion etching (D-RIE) method, and the like are adoptable.
(e) By isotropic etching, the upper insulating film 620 and the lower insulating film 610 are removed, and at the same time, the insulator layer 510 is removed by etching. In such a way, the first movable portion 10 obtained by patterning the semiconductor layer 520 is formed. Although not shown, the second movable portion 20 is formed simultaneously with the first movable portion 10. At this time, a width of the slits S, a pitch interval of the slits S and a time of the isotropic etching are adjusted appropriately, whereby a part of the insulator layer 510 is left as the first support portion 51 and the second support portion 52. In such a manner as described above, the MEMS device 1 is completed.

In accordance with the method of fabricating the MEMS device 1 according to the first embodiment, which is as described above, the first movable electrode 11 and the second movable electrode 21 are displaced in the directions reverse to each other in the case where the external force is applied to the MEMS device 1, whereby a MEMS device that detects the external force with high sensitivity can be provided.

### Second Embodiment

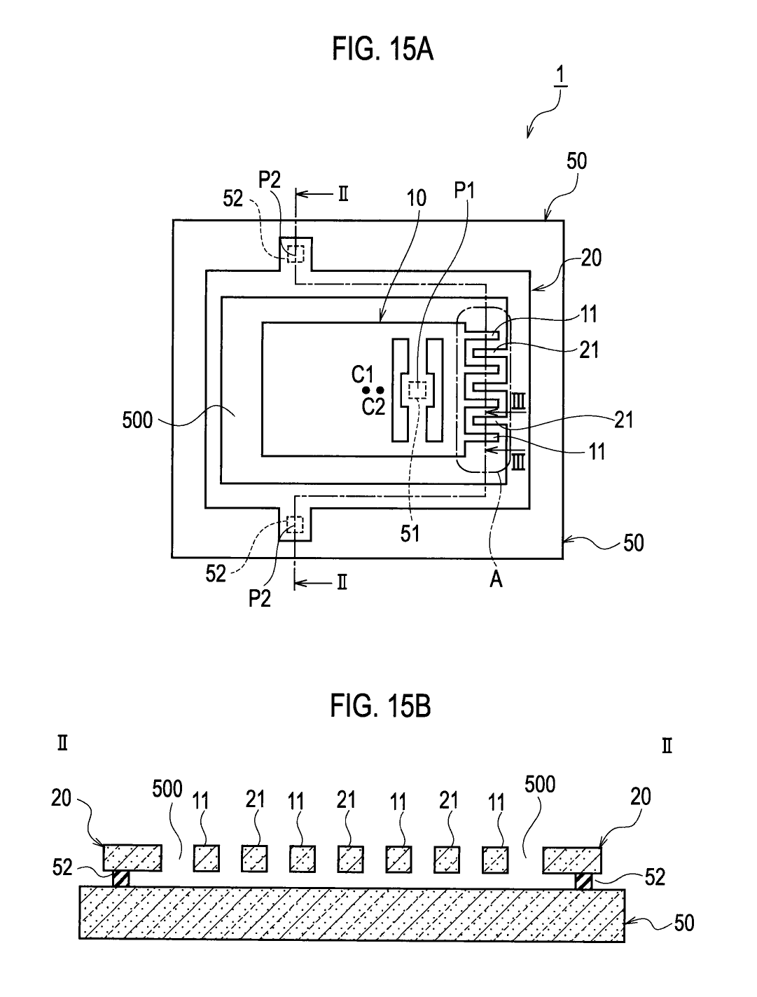

As shown in FIG. 15A and FIG. 15B, a MEMS device 1 according to a second embodiment is different from the MEMS device 1 shown in the first embodiment in that the second movable portion 20 is arranged so as to surround a periphery of the first movable portion 10 while interposing a space 500 therebetween.

As shown in FIG. 15A, at a support position P1 between a gravitational center position C1 of the first movable portion 10 and an opposite position A where a first movable electrode 11 and a second movable portion 20 are opposed to each other, the first movable portion 10 is fixed to a first support portion 51. Meanwhile, at support positions P2 opposed to the opposite position A while sandwiching a gravitational center position C2 of the second movable portion 20 therebetween, the second movable portion 20 is fixed to second support portions 52. Specifically, when viewed along the x-direction, the gravitational center position C1, the support position P1 and the opposite position A are sequentially arranged, and the support positions P2, the gravitational center position C2 and the opposite position A are sequentially arranged. Note that, since the second movable portion 20 is fixed to the second support portions 52 at two spots along the y-direction, displacement thereof in the y-direction by the external force is suppressed.

In the MEMS device 1 according to the second embodiment, at the opposite position A, shapes of mutually opposed portions of the first movable portion 10 and the second movable portion 20 are individually comb-tooth shapes, and the first movable electrode 11 and the second movable electrode 21 are arranged in an interdigital fashion.

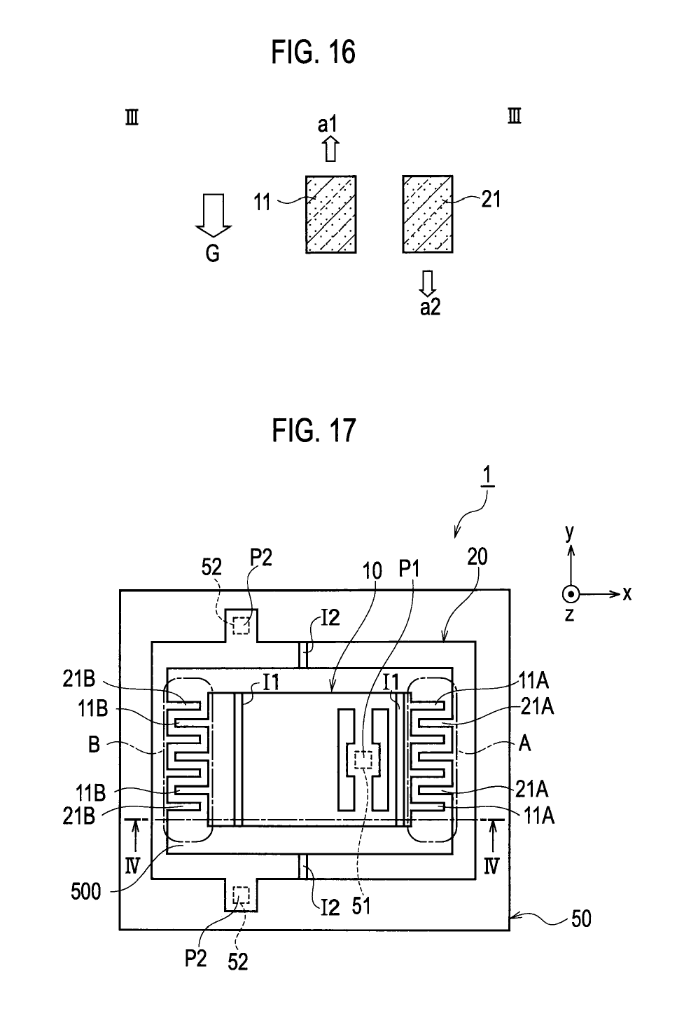

As shown in FIG. 16, for example, in the case where the gravitational acceleration G in the −z-direction is applied to the MEMS device 1 according to the second embodiment, the first movable electrode 11 is displaced in the +z-direction as shown by an arrow a1, and the second movable electrode 21 is displaced in the −z-direction as shown by an arrow a2. Hence, in accordance with the MEMS device 1 according to the second embodiment, a change of electrostatic capacitance between the first movable electrode 11 and the second movable electrode 21, which are displaced in the directions reverse to each other in the case where the external force is applied to the MEMS device 1, is sensed, whereby the external force applied to the MEMS device 1 can be detected with high sensitivity.

Note that, in a similar way to the description in the first embodiment, which is made with reference to FIG. 3 to FIG. 7, also in the MEMS device 1 according to the second embodiment, an upper surface of the first movable electrode 11 and an upper surface of the second movable electrode 21 are not allowed to be flush with each other, whereby the direction of the gravitational acceleration G can be sensed.

Moreover, in accordance with the MEMS device 1 according to the second embodiment, a device area thereof can be reduced as compared with the MEMS device 1 shown in FIG. 1A, in which the first movable portion 10 and the second movable portion 20 are arranged parallel to each other. Others are substantially similar to the first embodiment, and a duplicate description is omitted.

### Modification Example

FIG. 17 shows a MEMS device 1 according to a modification example of the second embodiment. In the MEMS device 1 shown in FIG. 17, an example is shown, where two side surfaces of the first movable portion 10, which extend in the y-direction and are opposed with each other, form opposite positions A and B where the first movable portion 10 is opposed to the second movable portion 20. In other words, the MEMS device 1 according to this modification example is different from the MEMS device 1 shown in FIG. 15A in that a plurality of the opposite positions where movable electrodes of the first movable portion 10 and movable electrodes of the second movable portion 20 are opposed to each other are provided.

As shown in FIG. 17, at the opposite position A, a first movable electrode 11A of the first movable portion 10 and a second movable electrode 21A of the second movable portion 20 are arranged in an interdigital fashion. Then, at the opposite position B, a first movable electrode 11B of the first movable portion 10 and a second movable electrode 21B of the second movable portion 20 are arranged in an interdigital fashion.

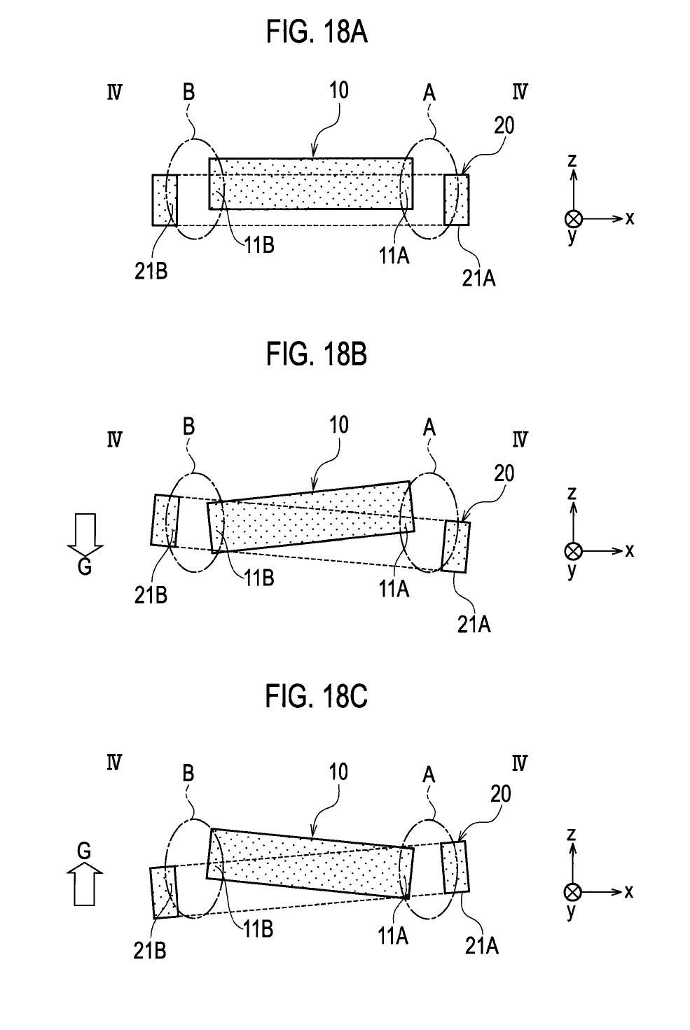

As shown in FIG. 18A, the MEMS device 1 is formed so that an upper surface of the first movable portion 10 and an upper surface of the second movable portion 20 cannot be flush with each other in a state where the external force is not applied in the z-direction. In an example shown in FIG. 18A, the upper surface of the first movable electrode 11A is higher than the upper surface of the second movable electrode 21A at the opposite position A, and the upper surface of the first movable electrode 11B is higher than the upper surface of the second movable electrode 21B.

As shown in FIG. 18B, in the case where the gravitational acceleration G in the −z-direction is applied to the MEMS device 1 according to the modification example of the second embodiment, then at the opposite position A, the first movable electrode 11A is displaced in the +z-direction, and the second movable electrode 21A is displaced in the −z-direction. At the opposite position B, the first movable electrode 11B is displaced in the −z-direction, and the second movable electrode 21B is displaced in the +z-direction. Therefore, immediately after the external force in the −z-direction is applied to the MEMS device 1, electrostatic capacitance between the first movable electrode 11A and the second movable electrode 21A is reduced at the opposite position A, whereas electrostatic capacitance between the first movable electrode 11B and the second movable electrode 21B is increased at the opposite position B.

Meanwhile, as shown in FIG. 18C, in the case where the gravitational acceleration G in the +z-direction is applied to the MEMS device 1 according to the modification example of the second embodiment, then at the opposite position A, the first movable electrode 11A is displaced in the −z direction, and the second movable electrode 21A is displaced in the +z-direction. At the opposite position B, the first movable electrode 11B is displaced in the +z-direction, and the second movable electrode 21B is displaced in the −z-direction. Therefore, immediately after the external force in the +z-direction is applied to the MEMS device 1, the electrostatic capacitance between the first movable electrode 11B and the second movable electrode 21B is reduced at the opposite position B, whereas the electrostatic capacitance between the first movable electrode 11A and the second movable electrode 21A is increased at the opposite position A.

As described above, the MEMS device 1 is formed so that the upper surface of the first movable portion 10 and the upper surface of the second movable portion 20 cannot be flush with each other, whereby the direction of the gravitational acceleration G can be sensed.

Moreover, in the MEMS device 1 according to the modification example of the second embodiment, a difference between a change in the electrostatic capacitance at the opposite position A and a change in the electrostatic capacitance at the opposite position B is calculated, whereby an absolute value of the change of the electrostatic capacitance is increased. In such a way, the detection sensitivity can be further enhanced.

In order to calculate the difference between the changes in the electrostatic capacitance, it is necessary to calculate a variation in the electrostatic capacitance at the opposite position A by measuring potentials of the first movable electrode 11A and the second movable electrode 21A, and at the same time, to calculate a variation in the electrostatic capacitance at the opposite position B by measuring potentials of the first movable electrode 11B and the second movable electrode 21B. Therefore, it is necessary to measure four potentials.

However, as shown in FIG. 17, an isolation layer I1 that electrically isolates the first movable electrode 11A and the first movable electrode 11b from each other is arranged in the first movable portion 10, and isolation layers I2 which electrically isolate the second movable electrode 21A and the second movable electrode 21B from each other are arranged in the second movable portion 20. In such a way, for example, the first movable electrode 11A and the second movable electrode 21B can be set at the same potential. In such a way, though four movable electrodes are provided in the MEMS device 1 shown in FIG. 17, three potentials are only required as the number of potentials to be measured.

### Third Embodiment

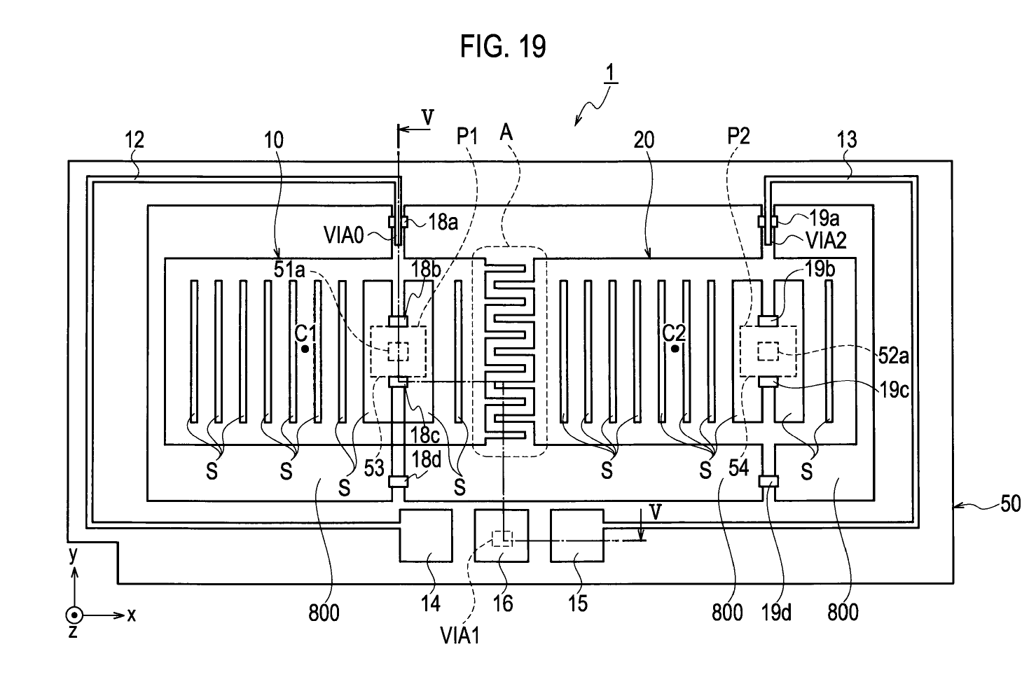

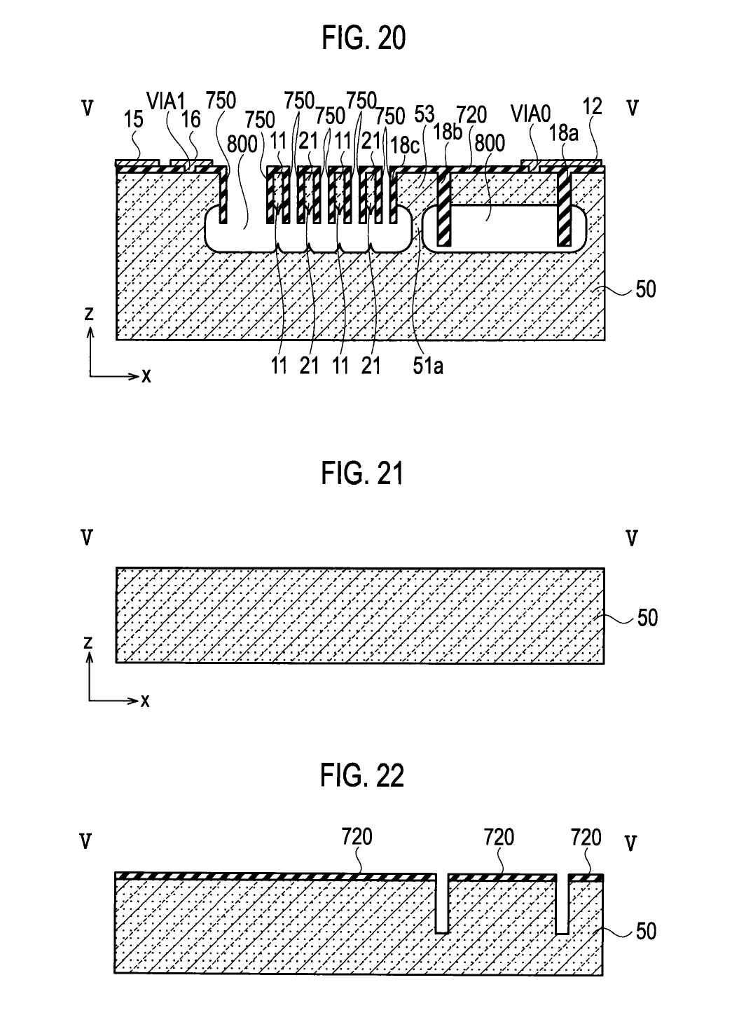

A schematic planar structure of a MEMS device according to a third embodiment is illustrated as shown in FIG. 19, and a schematic cross-sectional structure of the MEMS device shown in FIG. 19, which is taken along a line V-V therein, is illustrated as shown in FIG. 20.

As shown in FIG. 19 and FIG. 20, the MEMS device 1 according to the third embodiment is different from the MEMS device 1 shown in FIG. 9 only in that the substrate 50 is formed of a single crystal substrate, and others are substantially similar to the MEMS device shown in FIG. 9.

As shown in FIG. 19 and FIG. 20, the MEMS device 1 according to the third embodiment includes: the substrate 50; a first support portion 51a and a second support portion 52a, which are arranged on the substrate 50; a first movable portion 10 that has a first movable electrode 11, is fixed to a first support portion 51a at a position apart from the first movable electrode 11, and is displaced by the external force; and a second movable portion 20 that has a second movable electrode 21 arranged opposite to the first movable electrode 11, is fixed to a second support portion 52a at a position apart from the second movable electrode 21, and is displaced by the external force. Between a gravitational center position C1 of the first movable portion 10 and an opposite position A where the first movable electrode 11 and the second movable electrode 21 are opposed to each other, the first movable portion 10 is fixed to the first support portion 51a. At a position opposed to the opposite position A while sandwiching a gravitational center position C2 of the second movable portion 20 therebetween, the second movable portion 20 is fixed to the second support portion 52a.

As shown in FIG. 20, the first support portion 51a and the second support portion 52a are formed of the same semiconductor material as that of the substrate 50. Moreover, the substrate 50 and a first fixation portion 53 are connected to each other while interposing the first support portion 51a therebetween, and the substrate 50 and a second fixation portion 54 are connected to each other while interposing the second support portion 52a therebetween.

Moreover, as shown in FIG. 20, sidewall insulating films 750 are formed on sidewall portions of the first movable electrode 11 and the second movable electrode 21.

Moreover, as shown in FIG. 19, on the substrate 50 around a peripheral portion of the first movable portion 10, a first movable portion-purpose wiring electrode 12 is arranged while interposing an upper insulating film 720 therebetween, and on the substrate 50 around a peripheral portion of the second movable portion 20, a second movable portion-purpose wiring electrode 13 is arranged while interposing the upper insulating film 720 therebetween. Moreover, the first movable portion-purpose wiring electrode 12 is connected to a first movable portion-purpose terminal electrode 14 arranged on the substrate 50 around the peripheral portion of the first movable electrode 10 while interposing the upper insulating film 720 therebetween, and the second movable portion-purpose wiring electrode 13 is connected to a second movable portion-purpose terminal electrode 15 arranged on the substrate 50 around the peripheral portion of the second movable portion 20 while interposing the upper insulating film 720 therebetween. Furthermore, between the first movable portion-purpose terminal electrode 14 and the second movable portion-purpose terminal electrode 15, a grounding substrate electrode 16 connected to the substrate 50 while interposing a VIA1 therebetween is arranged on the upper insulating film 720.

Moreover, insulating isolation regions 18a, 18b, 18c and 18d for insulating the first movable portion 10 from the substrate 50 are formed, for example, by using the Deep trench isolation (DTI) technology. In a similar way, insulating isolation regions 19a, 19b, 19c and 19d for insulating the second movable portion 20 from the substrate 50 are also formed by using the DTI technology.

In the MEMS device 1 shown in FIG. 19, the first movable portion 10 is fixed to the first support portion 51a and the first fixation portion 53 at a support position P1 in a beam portion sandwiched between slits S, and the second movable portion 20 is fixed to the second support portion 52a and the second fixation portion 54 at a support position P2 in a beam portion sandwiched between slits S. Therefore, connection portions of the first movable portion 10 and the second movable portion 20 to the substrate 50 have flexibility, and the first movable portion 10 and the second movable portion 20 are likely to oscillate by the external force. In such a way, detection sensitivity of the MEMS device 1 is enhanced.

In FIG. 19, a direction perpendicular to a page surface thereof is defined as a z-direction, and a right-and-left direction on the page surface, that is, a direction of a straight line that connects the gravitational center position C1 of the first movable portion 10 and the gravitational center position C2 of the second movable portion 20 to each other is defined as an x-direction. Moreover, a direction perpendicular to the x-direction on the page surface, that is, an up-and-down direction thereon is defined as a y-direction. Note that a direction perpendicularly upward from the page surface is defined as a positive z-direction (+z-direction), and a direction toward the gravitational center position C2 from the gravitational center position C1 is defined as a positive x-direction (+-x-direction).

Hence, when viewed along the x-direction where the gravitational center position C1 and the gravitational center position C2 are connected to each other, the gravitational center position C1, the support position P1 and the opposite position A where the first movable electrode 11 and the second movable electrode 21 are opposed to each other are sequentially arranged, and the opposite position A, the gravitational center position C2 and the support position P2 are sequentially arranged.

The first movable portion 10 and the second movable portion 20 are oscillators which oscillate about positions thereof fixed individually to the first support portion 51a and the second support portion 52a, such fixed positions being taken as fulcrums. When the external force in the z-direction is applied from the outside to the MEMS device 1, a distance between the first movable electrode 11 and the second movable electrode 21 is changed. Therefore, when the external force is applied to the MEMS device 1 in a state where a voltage is applied to the first movable electrode 11 and the second movable electrode 21, the change of the distance between the first movable electrode 11 and the second movable electrode 21 is sensed as a change of electrostatic capacitance between the first movable electrode 11 and the second movable electrode 21.

The MEMS device 1 according to the third embodiment transmits the sensed change of the electrostatic capacitance to a signal processing circuit (not shown) by a detection signal. The signal processing circuit processes the detection signal and detects a gravitational acceleration applied to the MEMS device 1 according to the third embodiment. Specifically, the MEMS device 1 according to the third embodiment is a part of an electrostatic capacitance type acceleration sensor that detects the gravitational acceleration based on the change of the electrostatic capacitance. The signal processing circuit maybe arranged on the same chip as a chip on which the MEMS device 1 according to the third embodiment is arranged, or may be arranged on a different chip from the chip on which the MEMS device 1 according to the third embodiment is arranged.

Note that the first movable electrode 11 and the second movable electrode 21 may be formed by individually arranging electrodes such as metal films on the first movable portion 10 and the second movable portion 20, which are made of a semiconductor. Alternatively, the first movable portion 10 and the second movable portion 20 may be used as the first movable electrode 11 and the second movable electrode 21, respectively. In this case, it is necessary that the first movable portion 10 and the second movable portion 20 be electrically insulated from each other.

In the MEMS device 1 according to the third embodiment, at the opposite position A, shapes of mutually opposed portions of the first movable portion 10 and the second movable portion 20 are individually comb-tooth shapes, and the first movable electrode 11 and the second movable electrode 21 are arranged in an interdigital fashion.

Note that, in a similar way to the description in the first embodiment, which is made with reference to FIG. 3 to FIG. 7, also in the MEMS device 1 according to the third embodiment, an upper surface of the first movable electrode 11 and an upper surface of the second movable electrode 21 are not allowed to be flush with each other, whereby the direction of the gravitational acceleration G can be sensed.

### (Fabrication Method)

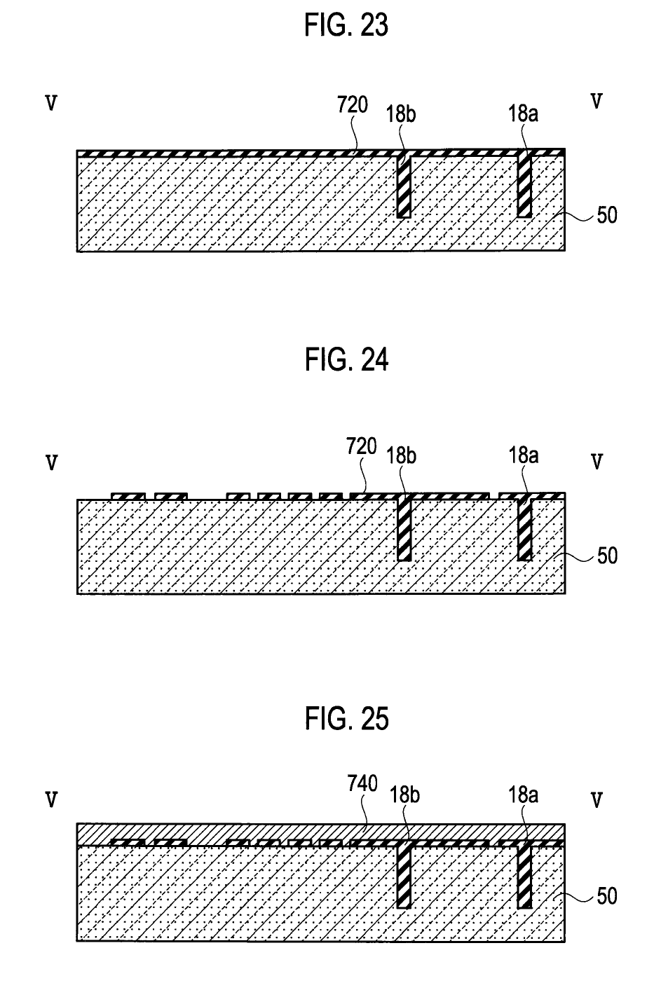

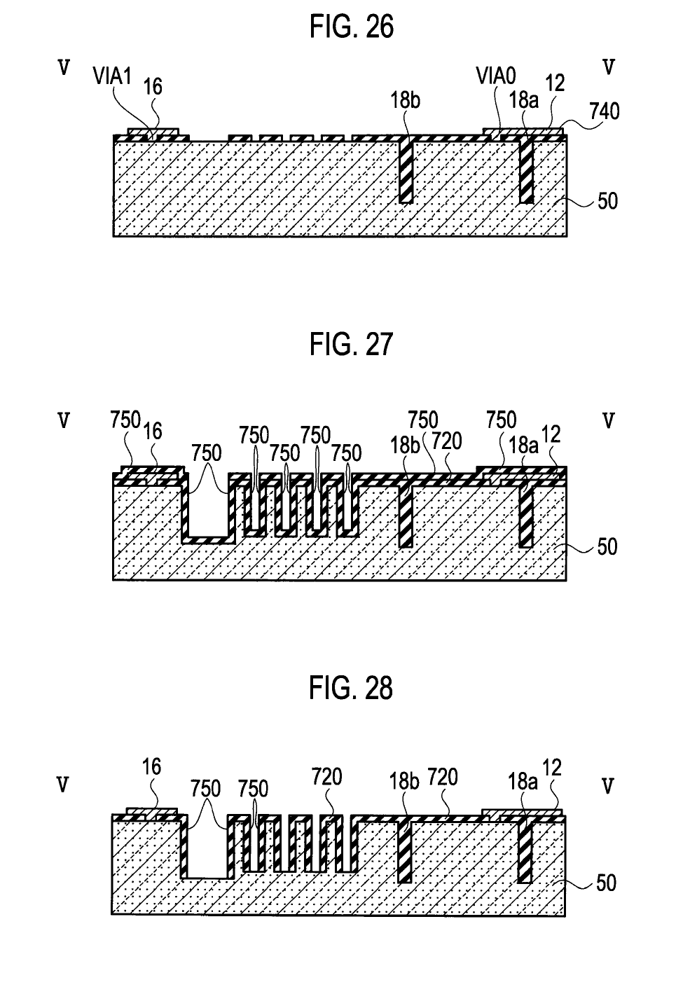

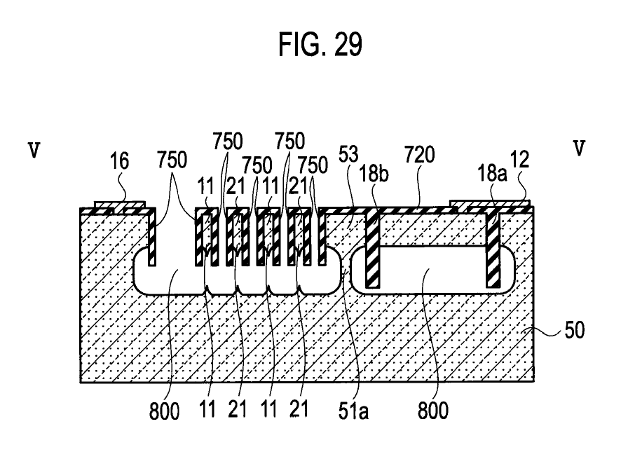

By using the MEMS device 1 shown in FIG. 19 and FIG. 20 as an example, a description is made of a method of fabricating the MEMS device 1 according to the third embodiment. In the MEMS device 1 shown in FIG. 19 and FIG. 20, a plurality of the slits S which penetrate the first movable portion 10 and the second movable portion 20 from the upper surfaces thereof to lower surfaces thereof are formed. These slits S are used in an etching step for separating the first movable portion 10 and the second movable portion 20 from the substrate 50. A description is made below of the method of fabricating the MEMS device 1 according to the third embodiment with reference to FIG. 21 to FIG. 29 which correspond to a cross section along the line V-V of FIG. 19. Although not shown, the second movable portion 20 is also formed in a similar way. Note that the method of fabricating the MEMS device 1, which is described below, is merely an example, and it is a matter of course that the MEMS device 1 is realizable by other various fabrication methods including modification examples of the method to be described below.
(a) As shown in FIG. 21, the substrate 50 made of single crystal is prepared. For example, a silicon (Si) substrate is adoptable for the substrate 50 made of the single crystal.
(b) Next, as shown in FIG. 22, for example, by using the thermal oxidation method, the upper insulating film 720 is formed on an upper surface of the substrate 50, further, a photoresist film (not shown) is formed on the upper insulating film 720, and this photoresist film is patterned into a desired shape by using the photolithography technology. Then, by selective etching using the patterned photoresist film as a mask, a part of the upper insulating film 720 is removed as shown in FIG. 22, and further, by using a deep reactive ion etching (D-RIE: Deep Reactive Ion Etching) technology and the like, trenches for forming the insulating isolation regions 18a and 18b for the substrate 50 are formed. The upper insulating film 720 is an insulator film such as a SiO₂ film.
(c) Next, as shown in FIG. 23, the insulating film is filled into the trenches, and the insulating isolation regions 18a and 18b are formed. In a similar way, the insulating isolation regions 18c, 18d, 19a, 19b, 19c and 19d are formed. Here, for the insulating film to be filled, for example, there are applicable a thermal oxidation film, an oxide film, a nitride film, a tetraethoxysilane (TEOS) film or the like, which is formed by a chemical vapor deposition (CVD) method.
(d) Next, as shown in FIG. 24, a photoresist film (not shown) is formed on the upper insulating film 720, and this photoresist film is patterned into a desired shape by using the photolithography technology. Then, by selective etching using the patterned photoresist film as a mask, a part of the upper insulating film 720 is removed as shown in FIG. 24.
(e) Next, as shown in FIG. 25, a metal electrode layer 740 is formed on the entire device surface. For example, the metal electrode layer 740 can be formed by vacuum evaporation or sputtering of aluminum (Al).
(f) Next, as shown in FIG. 26, the metal electrode layer 740 is patterned and etched, whereby the first movable portion-purpose wiring electrode 12, the second movable portion-purpose wiring electrode 13, the first movable portion-purpose terminal electrode 14, the second movable portion-purpose terminal electrode 15 and the grounding substrate electrode 16 are formed. Here, the first movable portion-purpose wiring electrode 12 is electrically connected to the first movable portion 10 through a VIA0, and the second movable portion-purpose wiring electrode 13 is electrically connected to the second movable portion 20 through a VIA2. Moreover, the grounding electrode 16 is electrically connected to the substrate 50 through the VIA1.
(g) Next, as shown in FIG. 27, by selective etching using the upper insulating film 720 as an etching mask, the substrate 50 is removed by etching to a predetermined depth. For the etching of the substrate 50, the Bosch process using the deep reactive ion etching (D-RIE) method, and the like are adoptable. Moreover, an insulating film 750 is deposited on the entire device surface. The insulating film 750 is also deposited on sidewall portions of etched grooves formed by the D-RIE method, whereby the sidewall insulating films 750 are formed. For example, an oxide film, a nitride film and the like, which are formed by the CVD method, are applicable as the insulating film 750.
(h) Next, as shown in FIG. 28, the insulating film 750 deposited on the device surface and bottom surfaces of the etched grooves is removed by etching. In such a way, there are exposed the respective surfaces of the first movable portion-purpose wiring electrode 12, the second movable portion-purpose wiring electrode 13, the first movable portion-purpose terminal electrode 14, the second movable portion-purpose terminal electrode 15 and the grounding substrate electrode 16. Moreover, a structure is obtained, in which the upper insulating film 720 is formed on the device surface, and the sidewall insulating films 750 are formed on side surfaces of the etched grooves.
(i) Next, as shown in FIG. 29, spaces 800 are formed by isotropic etching for the substrate 50, whereby the first movable portion 10 obtained by patterning the substrate 50 is formed. Although not shown, the second movable portion 20 is formed simultaneously with the first movable portion 10. At this time, a width of the slits S, a pitch interval of the slits S and a time of the isotropic etching are adjusted appropriately, whereby a part of the substrate 50 is left as the first support portion 51a, the first fixation portion 53, the second support portion 52a and the second fixation portion 54. Moreover, on the sidewall portions of the first movable electrode 11 and the second movable electrode 21, the sidewall insulating films 750 are formed to approximately the same depth as that of the insulating isolation regions 18a and 18b. Furthermore, surfaces of the first movable electrode 21 and the second movable electrode 21, which are opposed to the substrate 50, are etched back by the above-mentioned isotropic etching for forming the spaces 800, and in addition, the insulating films are not formed on the surfaces concerned. In such a manner as described above, the MEMS device 1 is completed.

In accordance with the MEMS device according to the third embodiment, which is as described above, the first movable electrode 11 and the second movable electrode 21 are displaced in the directions reverse to each other in the case where the external force is applied to the MEMS device concerned, whereby the external force can be detected with high sensitivity.

In addition, in accordance with the method of fabricating the MEMS device according to the third embodiment, the single crystal substrate is used, whereby a fabrication process of the MEMS device is simplified, and the MEMS device can be fabricated inexpensively.

### Other Embodiments

As mentioned above, the present invention has been described based on the embodiments; however, it should not be understood that the description and the drawings, which form a part of the disclosure, limit this invention. From this disclosure, a variety of alternative embodiments, examples and operation technologies will be obvious for those skilled in the art.

In the descriptions of the embodiments, which have been already made, the examples where the MEMS device is applied for the acceleration sensor are illustrated. However, the usage purpose of the MEMS device is not limited to the acceleration sensor, and the MEMS device is usable for a variety of sensors which detect the physical quantity by using a structure displaced in response to the external force, and the like. For example, the MEMS device is also applicable for an angular velocity sensor, a pressure sensor, a force sensor and the like.

As described above, it is a matter of course that the present invention incorporates a variety of embodiments and the like, which are not described herein. Hence, the technical scope of the present invention should be determined only by the invention specifying items according to the scope of claims reasonable from the above description.

### INDUSTRIAL APPLICABILITY

The MEMS device of the present invention is usable for an electronic instrument industry including a fabrication industry that fabricates a sensor having a movable portion.

What is claimed is:

1. A MEMS device comprising:
a substrate;
a first support portion and a second support portion, the first and second support portions being arranged on the substrate;
a first movable portion that has a first movable electrode, is fixed to the first support portion at a position apart from the first movable electrode, and is displaced by external force; and
a second movable portion that has a second movable electrode arranged opposite to the first movable electrode, is fixed to the second support portion at a position apart from the second movable electrode, and is displaced by the external force,
wherein the first movable portion is fixed to the first support portion between a gravitational center position of the first movable portion and an opposite position where the first movable electrode and the second movable electrode are opposed to each other, and the second movable portion is fixed to the second support portion at a position opposed to the opposite position while sandwiching a gravitational center position of the second movable portion therebetween.

2. The MEMS device according to claim 1,
wherein shapes of mutually opposed portions of the first movable portion and the second movable portion are individually comb-tooth shapes, and the first movable electrode and the second movable electrode are arranged in an interdigital fashion.

3. The MEMS device according to claim 1,
wherein the substrate includes an SOI substrate.

4. The MEMS device according to claim 1,
wherein the substrate includes a single crystal substrate.

5. The MEMS device according to claim 1,
wherein the second movable portion is arranged so as to surround a periphery of the first movable portion.

6. The MEMS device according to claim 5,
wherein a plurality of the opposite positions are provided.

7. The MEMS device according to claim 1,
wherein, at the opposite position, an upper surface of the first movable electrode and an upper surface of the second movable electrode are not flush with each other.

8. The MEMS device according to claim 1,
wherein the first movable electrode and the second movable electrode include cap layers on upper surfaces or lower surfaces thereof.

9. The MEMS device according to claim 7,
wherein, at the opposite position, a cap layer different in coefficient of linear expansion from the first movable portion and the second movable portion is arranged on at least either one of the first movable portion and the second movable portion.

10. The MEMS device according to claim 7,
wherein, at the opposite position, a film thickness of the first movable portion and a film thickness of the second movable portion are different from each other.

11. The MEMS device according to claim 1,
wherein each of the first movable portion and the second movable portion includes at least one slit that penetrates each of the first movable portion and the second movable portion from an upper surface thereof to a lower surface thereof.

12. The MEMS device according to claim 1,
wherein at least either one of the first movable electrode and the second movable electrode is displaced upward or downward.

13. The MEMS device according to claim 1,
wherein, in the first movable portion, the gravitational center position, the support position and the opposite position are arranged on a same axis in this order.

14. The MEMS device according to claim 1,
wherein, in the first movable portion, the gravitational center position, the support position and the opposite position are arranged on a same axis in this order, and in the second movable portion, the opposite position, the gravitational center position and the support position are arranged on a same axis in this order.

15. The MEMS device according to claim 5,
wherein, in the first movable position and the second movable position, the gravitational center positions, the support positions and the opposite position are arranged on a same axis in this order.

16. The MEMS device according to claim 6,
wherein the plurality of opposite positions exist on an extension on a same axis.

17. The MEMS device according to claim 4,
wherein the first movable electrode and the second movable electrode include an upper insulating film on upper surfaces thereof, and include sidewall insulating films on sidewall portions thereof.

18. The MEMS device according to claim 3,
wherein the first support portion and the second support portion are formed of a part of an insulating layer that composes the SOI substrate.

19. The MEMS device according to claim 4,
wherein the first support portion and the second support portion are formed of a part of the substrate.

20. The MEMS device according to claim 1,
wherein, in a case where the external force is applied to the MEMS device, electrostatic capacitance of one of the first movable electrode and the second movable electrode is increased, electrostatic capacitance of other of the first movable electrode and the second movable electrode is decreased, and a difference in electrostatic capacitance between the first movable electrode and the second movable electrode is outputted as a signal.

21. A method of fabricating a MEMS device including a first movable portion and a second movable portion opposed to the first movable portion, the method comprising the steps of:
forming an upper insulating film on an upper surface of a substrate made of single crystal;
patterning the upper insulating film, and forming trenches;
filling an insulating film into the trenches, and forming insulating isolation regions;
patterning the upper insulating film, and forming a metal electrode layer on an entire device surface;
patterning the metal electrode layer, and forming a first movable portion-purpose wring electrode connected to the first movable portion and a second movable portion-purpose wiring electrode connected to the second movable portion;
etching the substrate to a predetermined depth by selective etching using the upper insulating film as a mask;
depositing an insulating film on the entire device surface, and forming sidewall insulating films on sidewall portions of etched grooves;
removing by etching the insulating films deposited on the device surface and bottom surfaces of the etched grooves, and exposing respective surfaces of the first movable portion-purpose wiring electrode and the second movable portion-purpose wiring electrode; and
by isotropic etching for the substrate, forming spaces, and forming the first movable portion and the second movable portion, the first and second movable portion being obtained by patterning the substrate.

22. The method according to claim 21,
wherein the step of forming the first movable portion and the second movable portion includes the step of leaving a part of the substrate as a first support portion and a second support portion by adjusting a width of a plurality of slits, an interval pitch of the slits and a time of the isotropic etching, the slits being provided in the first movable portion and the second movable portion.

23. The method according to claim 21,
wherein, on sidewall portions of the first movable electrode and the second movable electrode, the sidewall insulating films are formed to approximately a same depth as a depth of the insulating isolation regions, and surfaces of the first movable electrode and the second movable electrode, the surfaces being opposed to the substrate, are etched back by the isotropic etching for forming the spaces.
